(19) United States
(12) Patent Application Publication
(10) Pub. No.: US 2024/0312869 A1
(43) Pub. Date: Sep. 19, 2024

(54) MICROFLUIDIC COOLING IN INTEGRATED CIRCUIT DEVICE

(71) Applicant: Intel Corporation, Santa Clara, CA (US)

(72) Inventors: Tongyan Zhai, Portland, OR (US); Telesphor Kamgaing, Chandler, AZ (US); Min Suet Lim, Gelugor (MY)

(73) Assignee: Intel Corporation, Santa Clara, CA (US)

(21) Appl. No.: 18/183,505

(22) Filed: Mar. 14, 2023

(51) Int. Cl. H01L 23/473; H01L 23/00; H01L 23/528

(52) U.S. Cl. CPC H01L 23/473; H01L 23/528; H01L 24/32; H01L 24/16; H01L 2224/16225; H01L 2224/32225

(57) ABSTRACT

Described herein are integrated circuit devices that include semiconductor devices near the center of the device, rather than towards the top or bottom of the device. In this arrangement, heat can become trapped inside the device. A microfluidic cooling layer is formed near a top or front the device, e.g., over the semiconductor devices and any front side interconnect structures, to transfer heat away from the semiconductor devices.

### BACKGROUND

Integrated circuit (IC) devices generate heat during operation that can degrade the performance of the devices. Reducing heat in an IC device can improve performance. If a device layer (e.g., transistors) are near the top or bottom of the IC package, heat can travel out of the top or bottom of the IC, e.g., to an integrated heat spreader and out of the IC package.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example , and not by way of limitation , in the figures of the accompanying drawings.

FIG. 1 illustrates an example IC architecture in which heat may become trapped, according to some embodiments of the present disclosure.

FIG. 2 illustrates an example IC device with a microfluidic cooling layer, according to some embodiments of the present disclosure.

FIG. 3 illustrates a cross-section of an IC device having a device layer, interconnect layers, dummy layers, and a microfluidic cooling layer, according to some embodiments of the present disclosure.

FIGS. 4A-4C provide a bottom view and two cross-sections of an example microfluidic cooling layer, according to some embodiments of the present disclosure.

FIGS. 5A through 5J illustrate a process for forming an IC device with a microfluidic cooling layer, according to some embodiments of the present disclosure.

FIGS. 6A-6D illustrate variations of the microfluidic cooling layer, according to some embodiments of the present disclosure.

FIGS. 7A and 7B are top views of, respectively, a wafer and dies that may include a microfluidic cooling layer in accordance with any of the embodiments disclosed herein.

FIG. 8 is a cross-sectional side view of an IC package that may include a microfluidic cooling layer in accordance with any of the embodiments disclosed herein.

FIG. 9 is a cross-sectional side view of an IC device assembly that may include a microfluidic cooling layer in accordance with any of the embodiments disclosed herein.

FIG. 10 is a block diagram of an example computing device that may include a microfluidic cooling layer in accordance with any of the embodiments disclosed herein.

### DETAILED DESCRIPTION

### Overview

Heat regulation is an important challenge in semiconductor devices. In general, when transistors operate at lower temperatures, they have improved performance. For example, electron mobility in transistors improves at lower temperatures, which can lead to increased drive currents. In addition, transistors at lower temperatures generally experience lower leakage than transistors operating at higher temperatures. These factors can result in smoother operations when an IC device (e.g., a computing device or transistor-based memory device) is operating at a lower temperature. For example, the voltage levels required to turn on a semiconductor device may be lower when the semiconductor device is at a lower temperature, due to the increased drive current. Thus, a semiconductor device at a lower temperature may have lower power consumption than if the device is at a higher temperature. Another effect of lower temperature in an IC device is that it increases the conductivity of the conductive components, which can also increase the speed of operations.

In previous IC arrangements, semiconductor devices (e.g., transistors) are formed over a substrate, and interconnect structures are formed over the semiconductor devices. Power and signal delivery may extend from the opposite side of the IC and through the interconnect structures. Heat primarily exits the device through the substrate side. For example, a heat spreader may be formed over the substrate to help heat from the transistors leave the IC, keeping the semiconductor materials cool.

Another IC architecture positions semiconductor devices nearer to the middle of the package. Interconnect structures may be formed both above and below the semiconductor devices. This architecture can improve power and signal delivery, e.g., by allowing power delivery from one side (e.g., the back side of the semiconductor devices), and signal delivery from the other side (e.g., the front side of the semiconductor devices). As another example, power delivery and signal input/output (I/O) may be on one side of the device layers (e.g., on a back side), while transfer of signals between components (e.g., between different processing units) in the package may be routed through interconnects on the opposite side of the device layers (e.g., on a front side).

When the transistors are in the middle of the IC, however, heat can get trapped within the IC package, rather than quickly dissipating out the front or back side, as in the previous architecture. Heating up the semiconductor devices may reduce performance, as discussed above. The heat trapping effect may be further exacerbated by inclusion of dummy layers on one or both sides of the semiconductor devices. In the manufacture of an IC, the number of interconnect layers, also referred to as metal layers, may be fixed. If a particular IC design does not use all of the layers, one or more dummy layers are fabricated. The dummy layers include an insulating material, and may include metal portions that are not connected to other layers.

Embodiments of the present disclosure may improve on at least some of the challenges and issues described above by providing a microfluidic cooling layer over the semiconductor devices. The microfluidic cooling layer may provide better heat transfer than a standard heat spreader, to move heat away from the semiconductor devices. Microfluidic channels may be formed in a carrier wafer that is attached to a front side of the semiconductor devices. A bonding material, e.g., a bonding oxide, may bond the carrier wafer to the front side of an IC device that includes the semiconductor devices. A hermetic surface treatment between the bonding oxide and the carrier wafer may hermetically seal the microfluidic channels. At least two ports are formed in the carrier wafer to provide access the microfluidic channels. During operation, a fluid flows through the microfluidic channels to cool the semiconductor devices. In some embodiments, different portions of the microfluidic cooling layer may have different designs, e.g., microfluidic channels may be larger or more concentrated over a high-heat region of the device layer.

In the following, some descriptions may refer to a particular S/D region or contact being either a source region/contact or a drain region/contact. However, unless specified otherwise, which region/contact of a transistor is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a support structure that includes electrically conductive interconnect structures for providing electrical connectivity between different IC components. Metal layers described herein may also be referred to as “interconnect layers” to clearly indicate that these layers include electrically conductive interconnect structures which may but does not have to be metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. As used herein, a “logic state” (or, alternatively, a “state” or a “bit” value) of a memory cell may refer to one of a finite number of states that the cell can have, e.g., logic states “1” and “0,” each state represented by a different voltage of the capacitor of the cell, while “READ” and “WRITE” memory access or operations refer to, respectively, determining/sensing a logic state of a memory cell and programming/setting a logic state of a memory cell. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

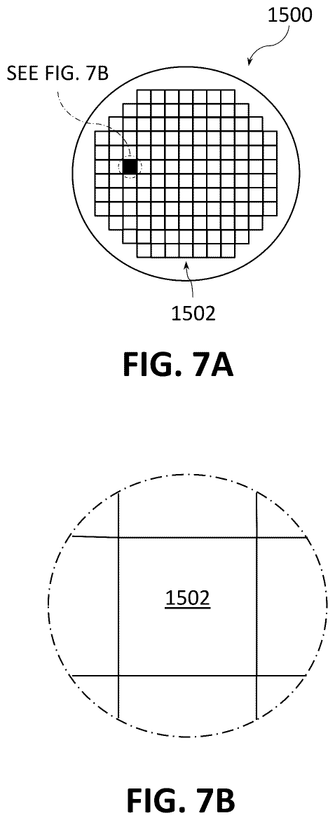

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 7A-7B, such a collection may be referred to herein without the letters, e.g., as “FIG. 7.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices incorporating microfluidic cooling as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

### Example IC With Dummy Region Over Device Layer

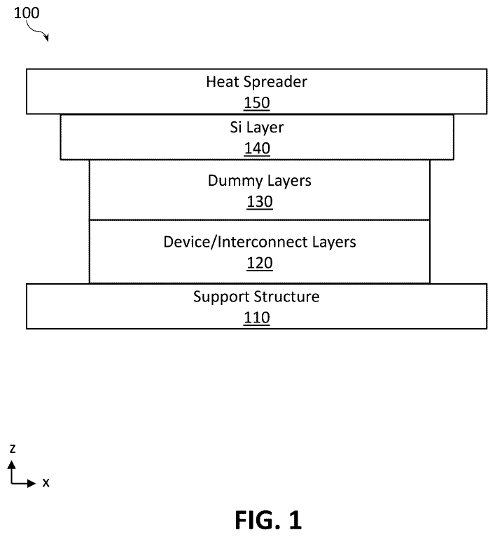

FIG. 1 illustrates an example IC architecture in which heat may become trapped. An IC device 100 includes a support structure 110, device and interconnect layers 120 over the support structure 110, and dummy layers 130 over the device and interconnect layers 120. The IC device 100 further includes a silicon layer 140 and a heat spreader 150 over the dummy layers 130.

The device and interconnect layers 120 include a set of interconnect layers over the support structure 110. These interconnect layers may enable power and signal delivery to the IC device 100. The interconnect layers may also enable intradevice communication. One or more device layers including semiconductor devices (e.g., transistors) are over the interconnect layers. In some cases, additional interconnect layers may be over the device layer(s). Dummy layers 130 are over the device and interconnect layers 120. The dummy layers 130 may be directly over a device layer, or a portion of a device layer. Alternatively, a dummy layer 130, or a portion of a dummy layer 130, may be over an interconnect layer.

In this arrangement, the device (transistor) layer(s) are neither at the top nor the bottom of the IC device 100. The dummy layers 130 sit between the device layer(s) and the heat spreader 150, and the dummy layers 130 may trap the heat within the device/interconnect layers 120. First, the dummy layers 130 sitting between the device/interconnect layers 120 and the heat spreader 150 create physical distance between the semiconductor devices and the heat spreader 150.

Furthermore, the materials forming the dummy layers 130, and in particular, a dielectric material in the dummy layers 130, are typically not good conductors of heat, and do not efficiently move heat from the device/interconnect layers 120 to the heat spreader 150. While metal materials that may form interconnects (e.g., copper) can move heat out of a device, the dummy layers 130 are not connected to the device/interconnect layers 120, and therefore may not effectively transfer heat out of the IC device 100.

### Example IC With Microfluidic Cooling Over Device Layer

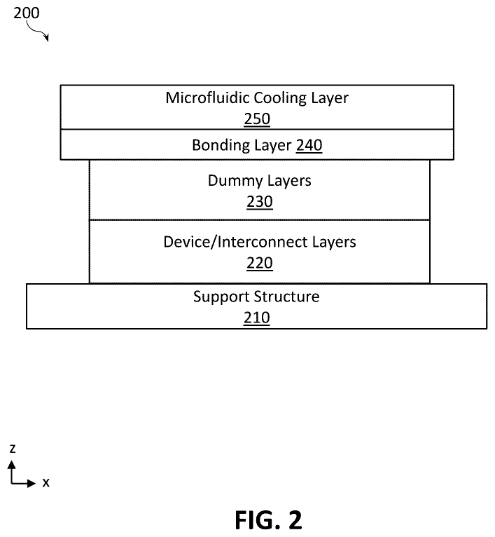

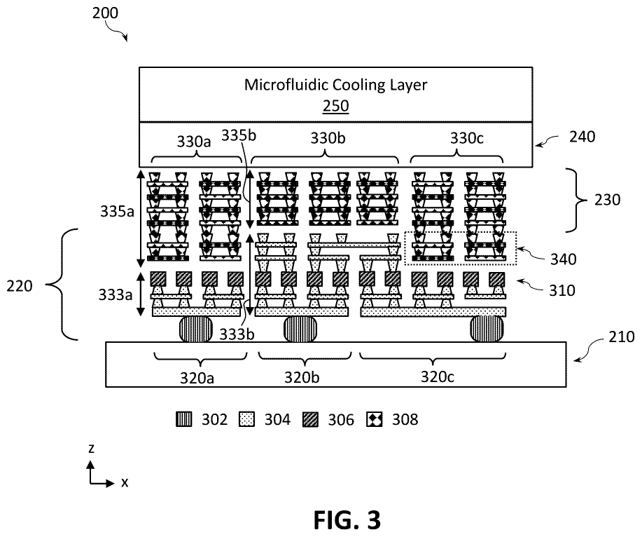

FIG. 2 illustrates an example IC device with a microfluidic cooling layer over the device layer(s), according to some embodiments of the present disclosure. The IC device 200 includes a support structure 210, device and interconnect layers 220 over the support structure 210, and dummy layers 230 over the device and interconnect layers 220. The support structure 210, device/interconnect layers 220, and dummy layers 230 are similar to the support structure 110, device/interconnect layers 120, and dummy layers 130 shown in FIG. 1. The IC device 200 further includes a bonding layer 240 and a microfluidic cooling layer 250 over the dummy layers 230 and the device/interconnect layers 220. In some embodiments, the dummy layers 230 are not included, and the bonding layer 240 and microfluidic cooling layer 250 are over the device/interconnect layers 220. The device/interconnect layers 220 may include dummy regions, as described with respect to FIG. 3.

The microfluidic cooling layer 250 includes microfluidic channels through which a fluid (e.g., a liquid coolant) can flow. The coolant draws heat from the device/interconnect layers 220 and transfers the heat away from the IC device 200 more effectively than the heat spreader 150 of FIG. 1. The fluid channels in the microfluidic cooling layer 250 may formed within a substrate, e.g., a carrier wafer, and the bonding layer 240 bonds the substrate to the IC device 200, and in this example, bonds the substrate to the IC device 200 over the dummy layers 230, on an opposite side of the device from the support structure 210.

The support structure 210 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. Although a few examples of materials from which the substrate may be formed are described here, any material that may serve as a foundation upon which an IC device as described herein may be built falls within the spirit and scope of the present disclosure.

A carrier wafer for forming the microfluidic cooling layer 250 may be similar to the support structure 210 described above. As described in further detail below, microfluidic channels are formed in the carrier wafer before the carrier wafer is attached to the IC device 200 as the microfluidic cooling layer 250.

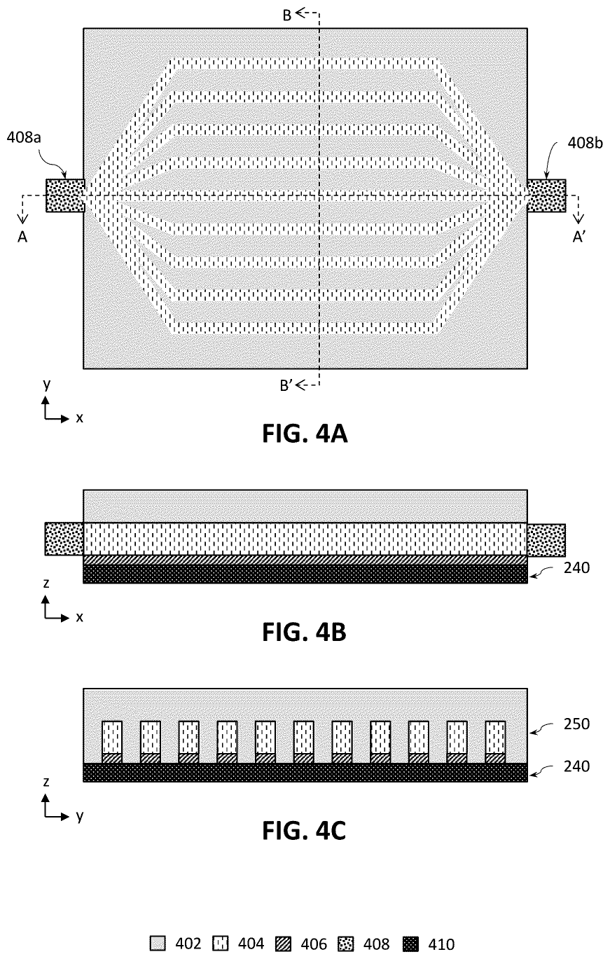

FIG. 3 illustrates a cross-section of an IC device having a device layer 310, interconnect layers over and under the device layer 310, dummy layers 230 over the device layer 310 and interconnect layers, and the microfluidic cooling layer 250 over the dummy layers 230, according to some embodiments of the present disclosure. FIG. 3 illustrates the device/interconnect layers 220 and dummy layers 230 of FIG. 2 in greater detail. Details of the microfluidic cooling layer 250 are shown in FIGS. 4-6, discussed below.

A number of elements referred to in the description of FIGS. 3 through 6 with reference numerals are illustrated in these figures with different patterns, with a legend showing the correspondence between the reference numerals and patterns being provided at the bottom of the drawing pages. For example, the legend in FIG. 3 illustrates that FIG. 3 uses different patterns to show solder balls 302, interconnects 304, transistors 306, and dummy interconnects 308.

The device/interconnect layers 220 include transistors 306 that are arranged in a device layer 310. While a single device layer 310 is illustrated, the IC device 200 may include multiple device layers at different heights in the z-direction. One or more device layers 310, or portions of such layer(s) including transistor devices, may generally be referred to as a device region. In this example, the device/interconnect layers 220 include three different regions 320a, 320b, and 320c, where different regions are located at different positions along the x-axis in the coordinate system shown. The different regions 320a, 320b, and 320c may correspond to different sub-devices with different functionalities. For example, the region 320a may be a central processing unit (CPU), the region 320c may be a graphical processing unit (GPU), and the region 320b may be a communications interface providing input and output for the IC device 200. In other embodiments, different regions may be associated with different functionalities. For example, other regions may include memory, digital signal processors (DSPs), various types of communications interfaces, other types of processors, etc.

Different portions of the device/interconnect layers 220 are illustrated as having different heights, where height refers to a dimension in the z-direction in the coordinate system shown. In addition to the regions 320a, 320b, and 320c, a second set of regions 330a, 330b, and 330c are illustrated, dividing the device/interconnect layers 220 in a different way. In particular, region 330a corresponds to the region 320a; region 330b corresponds to the region 320b and a portion of the region 320c; and region 330c corresponds to the remaining portion of the region 320c. In the region 330a, the transistors 306 and interconnect 304 have a height 333a, and in the region 330b, the transistors 306 and interconnect 304 has a height 333b, which is greater than the height 333a. In this case, in the region 330b, the device/interconnect layers 220 include several layers of interconnect 304 formed over the transistors 306, with interconnects 304 formed in the region 330b. In the regions 330a and 330c, in the portion of the device/interconnect layers 220 over the device layer 310), dummy interconnects 308 are formed instead of the interconnects 304. For example, the dummy region 340 includes dummy interconnects 308 over a portion of the device layer 310 in the region 330c. The interconnect layers formed over the device layer 310 in the region 330b may provide interconnections between the communications interface and the GPU in the example described above. In other embodiments, different regions may also have transistors 306 formed in various layers at various heights, rather than a single layer 310 extending across the different regions 320. A layer of an IC device including interconnects 304 may generally be referred to as an interconnect layer, and a region of an IC device including interconnects 304 may generally be referred to as an interconnect region.

As noted above, dummy layers 230 are formed over the device/interconnects layers. The dummy layers 230 include dummy interconnects 308 that are formed into dummy interconnect structures. A region of an IC device including dummy interconnects 308 (e.g., the dummy layers 230 and the dummy region 340) may generally be referred to as a dummy region, or dummy interconnect region. Different dummy regions may have different heights. For example, the dummy region in the region 330a extends through the dummy layers 230 and into a dummy region of the device/interconnect layers 220; this dummy region has a height 335a. An adjacent dummy region in the region 330b extends only through the dummy layers 230 and has a height 335b.

The dummy interconnects 308 may include the same materials as the interconnects 304 (discussed in greater detail below), but the dummy interconnects are not electrically coupled to other parts of the device (e.g., the dummy interconnects 308 are not coupled to the interconnects 304 or the transistors 306). In other embodiments, the dummy interconnects 308 may be formed from a different material from the interconnects 304. The interconnects 304 and dummy interconnects 308 may be formed using processes for patterning and depositing interconnect as are known in the art. In some cases, a fabrication process may include a fixed number of metallization layers, even if the metallization layers are not used. If a region of a metallization layer is not used, the dummy interconnect structures may be formed in the region. If a full metallization layer is not used, a dummy interconnect layer may be formed. In this example, a number of dummy interconnect layers are formed across the full device.

The computing regions 320a, 320b, and 320c are formed over interconnect layers that include a metallization stack and one or more solder balls 302. The solder balls 302 provide electrical and mechanical contact to the support structure 210, which may be in turn be coupled to other external components, e.g., for input and output of signals, and input of power to the IC device 200. The IC device 200 may have other alternative configurations to route electrical signals from the device/interconnect layers 220 and out of the IC device 200. For example, the solder balls 302 may be replaced by or may further include other analogous features (e.g., posts) that route the electrical signals to external components.

The interconnects 304 form layers of a metallization stack, where each layer may include an insulating material formed in multiple layers, as known in the art. The insulating material is not specifically shown in FIGS. 3-6. The interconnects 304 may include one or more conductive traces and conductive vias, providing one or more conductive pathways through the insulating materials. The interconnects 304 may be formed from appropriate conductive material, such as copper, silver, nickel, gold, aluminum, or other metals or alloys, for example. The conductive pathways may be connected to one another in any suitable manner. While all of the interconnects 304 in FIG. 3 are illustrated as being formed form the same material, in other embodiments, different materials may be used, e.g., the interconnects over a front side of the device layer 310 may include a different material from the interconnects below the back side of the device layer 310. Although FIG. 3 illustrates a specific number and arrangement of conductive pathways formed by the interconnects 304, these are simply illustrative, and any suitable number and arrangement may be used.

Different metal layers may have different thicknesses, i.e., heights in the z-direction in the coordinate system shown. In the portion of the device/interconnect layers 220 below the device layer 310, lower metal layers (i.e., layers closer to the solder balls 302) may be thicker than higher metal layers (i.e., layers closer to the device layer 310). Each layer may have a different thickness, e.g., moving up in the z-direction, each metal layer is thinner than the layer below, or the layers may be staggered, e.g., with one set of layers (e.g., two, three, four, or more layers) at one thickness, and the next set of layers at a different thickness. In the portion of the device/interconnect layers 220 above the device layer 310, lower metal layers (i.e., layers closer to the device layer 310) may be thinner than higher metal layers (i.e., layers closer to the oxide layer 240). As with the layers below the device layer 310, each layer above the device layer 310 may have a different thickness, e.g., increasing in thickness in the z-direction, or the thicknesses may be staggered, as described above.

In some embodiments, the insulating material surrounding the interconnects 304, the transistors 306, and/or the dummy interconnects 308 may include a dielectric material, such as silicon dioxide, silicon nitride, oxynitride, polyimide materials, glass reinforced epoxy matrix materials, or a low-k or ultra-low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material may include a semiconductor material, such as silicon, germanium, or a III-V material (e.g., gallium nitride), and one or more additional materials. For example, the insulating material may include silicon oxide or silicon nitride. An insulating material in the device layer 310 may be different from insulating materials around the interconnects 304 above and/or below the device layer 310.

The interconnects 304 form conductive pathways to route power, ground, and/or signals to/from various components of the device layer 310. The device layer 310 includes logic devices, e.g., transistors 306, coupled to the interconnects 304, e.g., through conductive contacts. The device layer 310 may include semiconductor material systems including, for example, N-type or P-type materials systems, as active materials (e.g., as channel materials of transistors). In some embodiments, the transistors 306 may include substantially monocrystalline semiconductors, such as silicon or germanium.

In some embodiments, the transistors 306 may include compound semiconductors, e.g., compound semiconductors with a first sub-lattice of at least one element from group III of the periodic table (e.g., Al, Ga, In), and a second sub-lattice of at least one element of group V of the periodic table (e.g., P, As, Sb). In some embodiments, the transistors 306 may include a binary, ternary, or quaternary III-V compound semiconductor that is an alloy of two, three, or even four elements from groups III and V of the periodic table, including boron, aluminum, indium, gallium, nitrogen, arsenic, phosphorus, antimony, and bismuth.

In some embodiments, the transistors 306 may be/include an intrinsic IV or III-V semiconductor material or alloy, not intentionally doped with any electrically active impurity. In alternate embodiments, nominal impurity dopant levels may be present within the transistors 306, for example to set a threshold voltage Vt, or to provide halo pocket implants, etc. In such impurity-doped embodiments however, impurity dopant level within the active materials may be relatively low, for example below about 10¹⁵ cm⁻³, and advantageously below 10¹³ cm⁻³.

For exemplary P-type transistor embodiments, transistors 306 may advantageously be formed using group IV materials having a high hole mobility, such as, but not limited to, Ge or a Ge-rich SiGe alloy. For some exemplary embodiments, such active materials may have a Ge content between 0.6 and 0.9, and advantageously is at least 0.7.

For exemplary N-type transistor embodiments, the transistors 306 may advantageously be formed using a III-V material having a high electron mobility, such as, but not limited to InGaAs, InP, InSb, and InAs. For some such embodiments, the active material may be a ternary III-V alloy, such as InGaAs or GaAsSb. For some InₓGa₁₋ₓAs fin embodiments, In content in the such active material may be between 0.6 and 0.9, and advantageously at least 0.7 (e.g., In_{0.7}Ga_{0.3}As).

In some embodiments, the transistors 306 may be formed from thin-film materials, in which embodiments the transistors 306 could be thin-film transistors (TFTs). A TFT is a special kind of a field-effect transistor (FET), made by depositing a thin film of an active semiconductor material, as well as a dielectric layer and metallic contacts, over a support structure that may be a non-conducting (and non-semiconducting) support structure. During operation of a TFT, at least a portion of the active semiconductor material forms a channel of the TFT, and, therefore, the thin film of such active semiconductor material is referred to herein as a “TFT channel material.” This is different from conventional, non-TFT, transistors where the active semiconductor channel material is typically a part of a semiconductor substrate, e.g., a part of a silicon wafer. In various such embodiments, active materials of the transistors 306 may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide.

In general, active materials of the transistors 306 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc.

### Example Microfluidic Cooling Layer

FIGS. 4A-4C provide a bottom view and two cross-sections of an example microfluidic cooling layer, according to some embodiments of the present disclosure. As noted with respect to FIG. 3, a number of elements are illustrated in FIG. 4 with different patterns, with a legend showing the correspondence between the reference numerals and patterns at the bottom of the drawing page. The legend in FIG. 4 illustrates that FIG. 4 uses different patterns to show a substrate material 402, microfluidic channels 404, sealant 406, ports 408, and bonding layer 410.

FIG. 4A illustrates one example bottom view of the microfluidic cooling layer 250. FIG. 4B illustrates a first cross-section of the microfluidic cooling layer 250 through the plane labelled AA′ in FIG. 4A. FIG. 4C illustrates a second cross-section of the microfluidic cooling layer 250 through the plane labelled BB′ in FIG. 4A.

The microfluidic cooling layer 250 includes multiple microfluidic channels 404 extending across the microfluidic cooling layer 250. The microfluidic channels 404 are formed in a substrate material 402. The microfluidic channels 404 extend from the bottom face of the microfluidic cooling layer 250 (shown in FIG. 4A) into the substrate material 402, i.e., they extend partially through the height of the substrate material 402 in the z-direction, as shown in FIGS. 4B and 4C.

The substrate material 402 may be any material suitable for forming the microfluidic channels therein. The substrate material 402 and, more generally, the microfluidic cooling layer 250 may provide support for the IC device 200. The substrate material 402 may be, for example, silicon, glass, photodefinable glass, or silicon carbide. In other examples, any of the materials described with respect to the support structure 210 may be used as the substrate material 402.

During fabrication of the microfluidic cooling layer 250, the microfluidic channels 404 may be etched from the substrate material 402 and filled with a sacrificial material, such as silicon dioxide (SiO2), polysilicon, or polyimide. After the IC device 200 has been fabricated and the microfluidic cooling layer 250 attached, a fluid (e.g., a coolant, or a solvent) may be pumped through the microfluidic channels 404 to remove the sacrificial material. Coolant may then replace the sacrificial material, or the material used to remove the sacrificial material, so that coolant flows through the microfluidic channels 404. The coolant may be, for example, purified water or deionized water.

A bonding layer 410 couples the microfluidic cooling layer 250 to the IC device 200, e.g., to the top dummy layer 230 as illustrated in FIGS. 2 and 3. The bonding layer 410 may be created using insulator-insulator bonding, e.g., as oxide-oxide bonding, where an insulating material of a first structure (e.g., the dummy layer 230) is bonded to an insulating material of a second structure (e.g., the microfluidic cooling layer 250). In some embodiments, a bonding material, such as a bonding oxide, may be present in between the faces of the structures that are bonded together. In general, to bond two structures together, the bonding material may be applied to one or both faces of the first and second structures that should be bonded. For example, the bonding material making up the bonding layer 410 is applied to the upper face of the dummy layer 230 and/or the lower face of the microfluidic cooling layer (in the orientation shown in FIG. 4). After the bonding material is applied, the first and second structures are put together, possibly while applying a suitable pressure and heating up the assembly to a suitable temperature (e.g., to relatively low temperatures, e.g., between about 50 and 200 degrees Celsius) for a duration of time. In some embodiments, the bonding material may be an adhesive material that ensures attachment of the first and second structures to one another. In some embodiments, the bonding material may be an etch-stop material. In some embodiments, the bonding material may be both an etch-stop material and have suitable adhesive properties to ensure attachment of the first and second structures to one another.

In some embodiments, the bonding material may include silicon, nitrogen, carbon, and oxygen, where the atomic percentage of any of these materials may be at least 1%, e.g., between about 1% and 50%, indicating that these elements are added deliberately, as opposed to being accidental impurities which are typically in concentration below about 0.1%. Using an etch-stop material at a bonding interface that includes include silicon, nitrogen, carbon, and/or oxygen, where the atomic percentage of any of these materials may be at least 1%, e.g., SiOCN, may be advantageous in terms that such a material may act both as an etch-stop material, and have sufficient adhesive properties to bond the first and second structures together.

A sealant 406 is between the bonding layer 410 and the microfluidic channels 404 to hermetically seal the microfluidic channels 404. The sealant 406 prevents the coolant from escaping the microfluidic channels 404 and entering the dummy layers 230 or lower active layers, e.g., the device layer 310. The sealant 406 may be, for example, silicon nitride, glass, polymer, or a metal. The sealant 406 may have a thickness of several nanometers to several microns. In some embodiments, the sealant 406 is located under the channels 404, as illustrated in FIG. 4. In other embodiments, the sealant 406 is spread in a single layer across the device 200, i.e., as a single layer between the substrate 402 and the bonding layer 410. In still other embodiments, the sealant 406 is located under the channels 404 and some portion of the substrate material 402 next to the channels 404, but not fully across the substrate material 402.

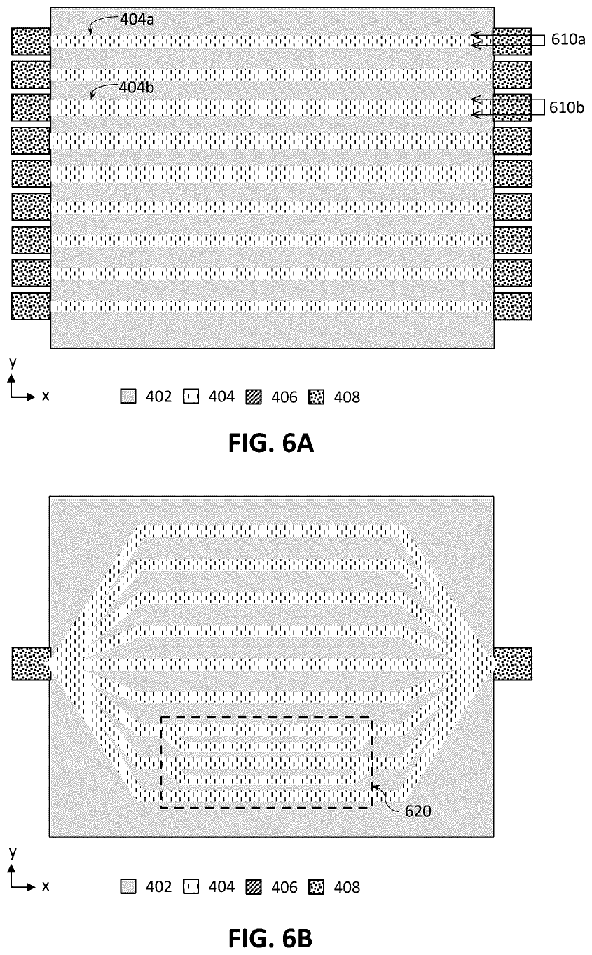

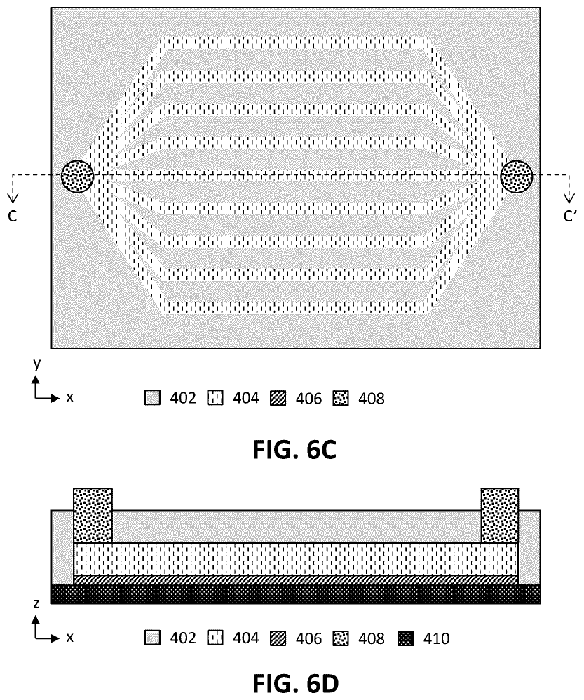

The substrate material 402 may have a thickness (i.e., a dimension in the z-direction in the orientation shown in FIG. 4) on the order of 100 microns to several millimeters, e.g., around 500-1000 microns. The channels 404 may have a height (i.e., a dimension in the z-direction in the orientation of FIG. 4) of approximately 1-100 microns, e.g., 2-10 microns. The channels 404 may have a width (i.e., a dimension in the y-direction in the orientation of FIG. 4) of approximately 1-100 microns, e.g., 2-10 microns. The sizes of different channels 404 may vary across different parts of an IC device, as described further with respect to FIG. 6.

A distance between adjacent channels 404 (i.e., a distance extending in the y-direction in the orientation of FIG. 4) may be, e.g., 1-100 microns. The distance between adjacent channels 404 and/or pitch of adjacent channels 404 may vary across different parts of an IC device, as described further with respect to FIG. 6, or the channels 404 may be evenly sized and spaced, e.g., as shown in FIG. 4.

In the example shown in FIG. 4, two ports 408 are coupled to the microfluidic channels 404. One port 408a may be an inlet, where a fluid flows into the microfluidic channels 404, and the other port 408b is an outlet, where the fluid flows out of the microfluidic channels 404. In this example, each of the microfluidic channels 404 are connected to the same pair of ports. The microfluidic channels 404 fan out from the inlet port 408a, extend across most of the width of the device at an even pitch, and then fan back in towards the outlet port 408b. In other embodiments, each microfluidic channel 404 may have its own pair of ports, or different groups of microfluidic channels may be coupled to different pairs of ports. In other embodiments, multiple channels may have a single inlet port and individual outlet ports, or vice versa. Other port arrangements may be used in other embodiments.

The ports 408 may be coupled to a fluid flow controller, e.g., a pump that controls the flow of the coolant through the ports 408 and the microfluidic channels 404. The IC device 200, or an external device coupled to the IC device 200, may include refrigeration, a heat pump, a heat sink, or another mechanism for cooling the coolant before it recirculated through the microfluidic channels 404.

In the example shown in FIG. 4, the ports 408 extends out the sides of the device 200, in line with the microfluidic channels 404. In other embodiments, the ports 408 may connect from a front side or a back side of the device 200. An example in which the ports 408 extend from the front side of the device is illustrated in FIG. 6.

### Example Process for Forming IC With Microfluidic Cooling Layer

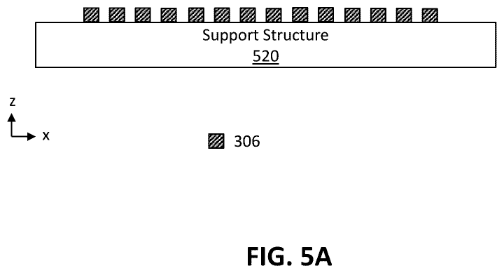

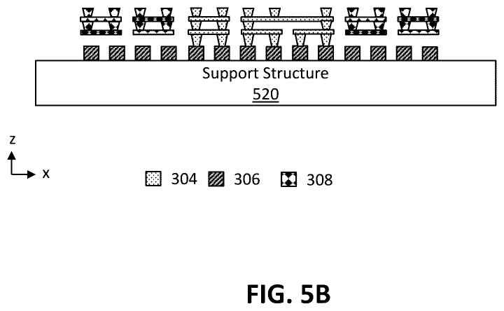

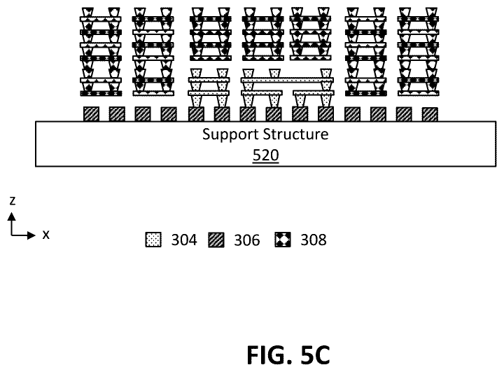

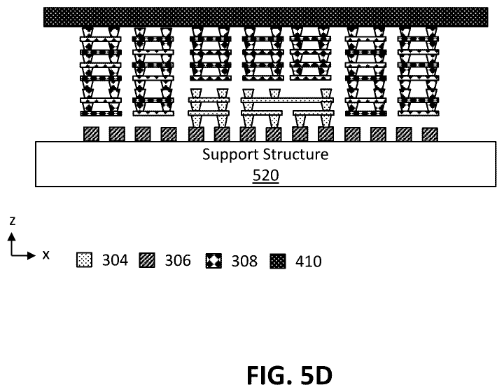

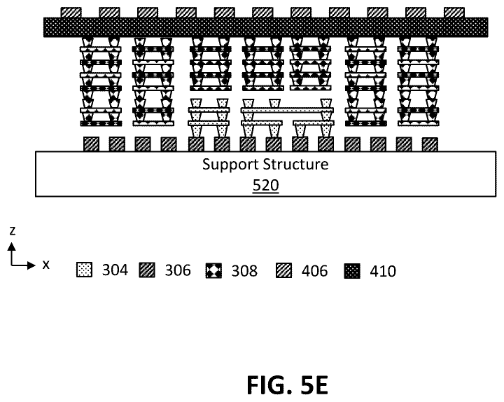

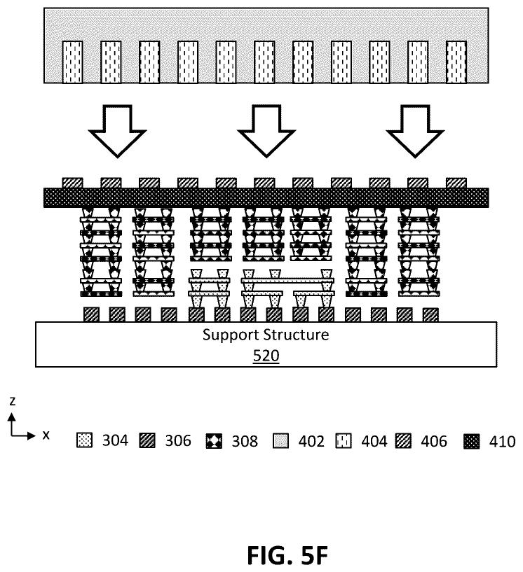

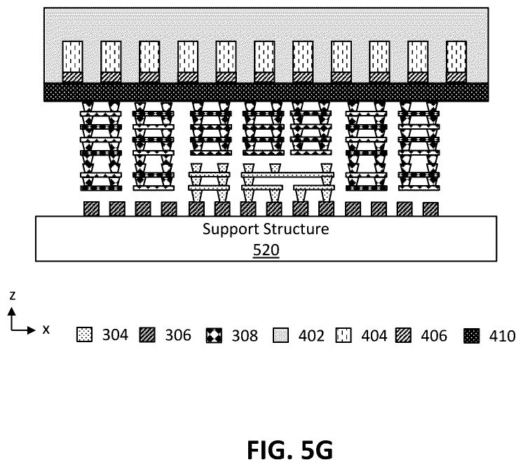

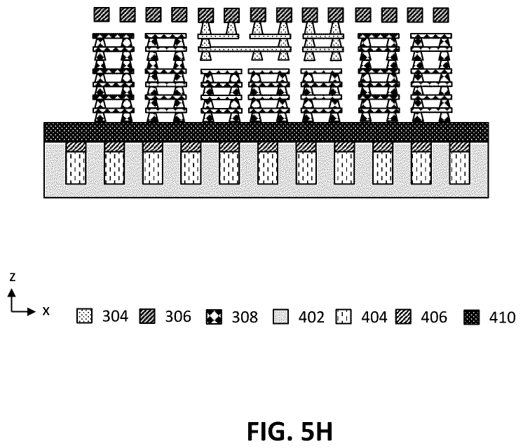

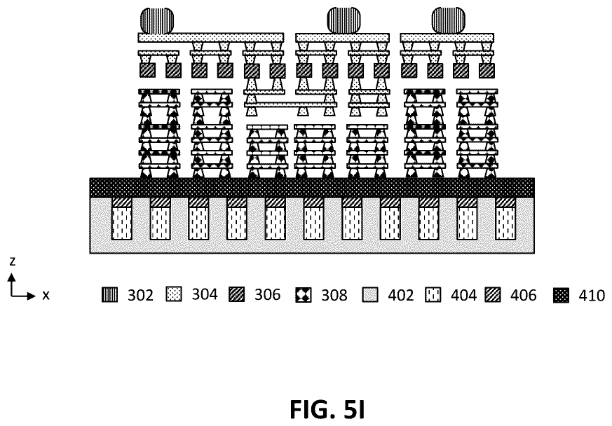

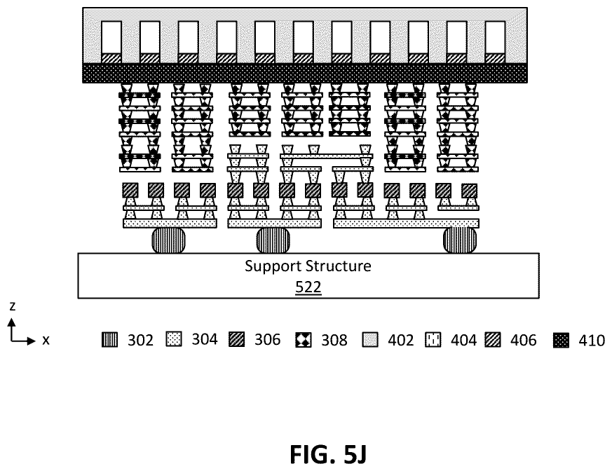

FIGS. 5A through 5J illustrate a process for forming an IC device with a microfluidic cooling layer, according to some embodiments of the present disclosure. A number of elements referred to in the description of FIGS. 5A through 5J with reference numerals are illustrated in these figures with different patterns, with a legend showing the correspondence between the reference numerals and patterns being provided at the bottom of the drawing pages. Some of the same patterns were used in FIGS. 3 and 4. For example, the legend in FIG. 5A illustrates that FIG. 5A uses a pattern to show transistors 306.

The transistors 306 may include any of the materials described above with respect to FIG. 3. The transistors 306 are formed over a support structure 520. The support structure 520 may be similar to the support structure 210 described with respect to FIG. 2. The transistors 306 may be surrounded by a dielectric material, not specifically shown in FIG. 5.

In FIG. 5B, interconnects 304 and dummy interconnects 308 are formed over the transistors 306. The interconnects 304 corresponds to the interconnects in the region 330b in FIG. 3. The dummy interconnects 308 corresponds to the dummy interconnect structures in the regions 330a and 330c in FIG. 3, e.g., the dummy region 340. The dummy interconnects 308 may include the same materials as the interconnects 304 but is not electrically coupled to other parts of the device (e.g., the dummy interconnects 308 are not coupled to the interconnects 304 or the transistors 306). In other embodiments, the dummy interconnects 308 may be formed from a different material from the interconnects 304.

The interconnects 304 and dummy interconnects 308 may be surrounded by a dielectric material, not specifically shown in FIG. 5. As noted above, in some embodiments, the dielectric material around the transistors 306 may be different from the dielectric material around the interconnects 304 and dummy interconnects 308. The interconnects 304 and dummy interconnects 308 may be formed using processes for patterning and depositing interconnect as are known in the art.

At FIG. 5C, additional layers of dummy interconnect 308 are fabricated in additional layers over the previously-fabricated layers of interconnect 304 and dummy interconnect 308. As noted above, in some cases, a fabrication process may include a fixed number of metallization layers, even if the metallization layers are not used. In this example, a number of dummy interconnect layers are formed across the full device.

In FIG. 5D, a bonding layer 410 is deposited over the dummy interconnect 308. While the bonding layer 410 is illustrated as being formed over the dummy interconnect 308, the bonding layer 410 is also deposited over the dielectric material surrounding the dummy interconnect. In some embodiments, one or more layers of dielectric material are formed over the dummy interconnect 308, and the bonding layer 410 includes the dielectric material or is deposited over the dielectric material. As noted above, in some embodiments, the dummy layers 230 are not included, and the bonding layer 410 may be formed over the structure shown in FIG. 5B, e.g., the device/interconnect layers 220.

In FIG. 5E, the sealant 406 is deposited on the bonding layer 410. In the example shown in FIG. 5, the sealant 406 is deposited in locations that the microfluidic channels 404 will be located. In other embodiments, the sealant 406 may be deposited across the bonding layer 410, or over a greater portion of the bonding layer 410.

In FIG. 5F, the substrate 402 with the microfluidic channels 404 formed therein is brought into contact with the bonding layer 410 and sealant 406, as indicated by the arrows. In some embodiments, a bonding material is applied to the substrate 402 prior to bonding it to the IC device. In some embodiments, the sealant 406 is applied over the microfluidic channels 404 (in particular, over the sacrificial material deposited in the microfluidic channels 404 during fabrication). The substrate 402 may be applied with a temperature and/or pressure to secure the substrate 402 to the IC device. In FIG. 5G, the substrate 402 is attached to the IC device via the bonding layer 410.

In FIG. 5H, the device is flipped, and the support structure 520 is removed, e.g., by grinding. In some embodiments, a portion of the support structure 520 remains. Through-substrate vias (TSVs) may be formed through the remaining portion of the support structure 520.

At FIG. 5I, back end interconnects 304 and solder balls 302 are fabricated over the exposed side of the transistors 306. At FIG. 5J, the device is again flipped, and a support structure 522 is coupled to the solder balls 302. The support structure 522 may be the support structure 210 shown in FIGS. 2 and 3. The device illustrated in FIG. 5I is similar to the device shown in FIGS. 2 and 3.

### Example Embodiments for Microfluidic Cooling Layer

FIGS. 6A-6D illustrate variations of the microfluidic cooling layer, according to some embodiments of the present disclosure. In FIG. 6A, each microfluidic channel 404 has its own pair of ports 408, i.e., a respective inlet port and outlet port. In addition, the microfluidic channels 404 do not all have the same width, e.g., the channel 404a has a first width 610a, and the channel 404b has a second width 610b, where the second width 610b is greater than the first width 610a. The microfluidic channels may have widths based on the heat generated by the region of the IC device under the microfluidic channels, e.g., channels extending over high-heat regions of a device (e.g., a CPU) may be wider than channels extending over lower-heat regions of a device (e.g., a memory).

In FIG. 6B, a portion 620 of the microfluidic channels 404 are positioned with greater density, i.e., less distance between adjacent channels, than in the example shown in FIG. 4A. In this example, several channels 404 are split into multiple branches, providing greater density within the portion 620. Said another way, the channels 404 within the portion 620 are arranged at a first pitch that is smaller than a second pitch of the channels 404 outside of the portion 620, where pitch refers to a center-to-center distance between closest adjacent structures, i.e., a center-to-center distance between neighboring channels 404. The microfluidic channels 404 may be arranged at varying pitches or densities based on the heat generated by the region of the IC device under the microfluidic channels, e.g., channels extending over high-heat regions of a device (e.g., a CPU) may be arranged with a narrower/smaller pitch than channels extending over lower-heat regions of a device (e.g., a memory).

FIGS. 6C and 6D illustrate an embodiment in which the ports 408 extend upwards in the z-direction rather than towards the sides of the IC device 200. FIG. 6D illustrates a cross-section taken through the plane CC′ annotated in FIG. 6C. In this example, the ports 408 extend through the top face of the substrate 402 and may connect to a fluid flow controller, e.g., a pump that controls the flow of the coolant through the microfluidic channels 404.

### Example Devices

Arrangements with one or more microfluidic cooling layers as disclosed herein may be included in any suitable electronic device. FIGS. 7-11 illustrate various examples of devices and components that may include a microfluidic cooling layer as disclosed herein.

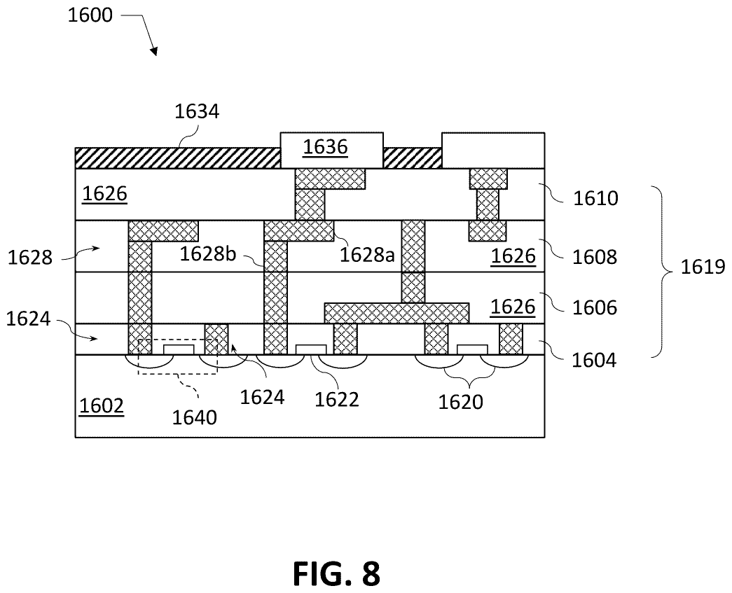

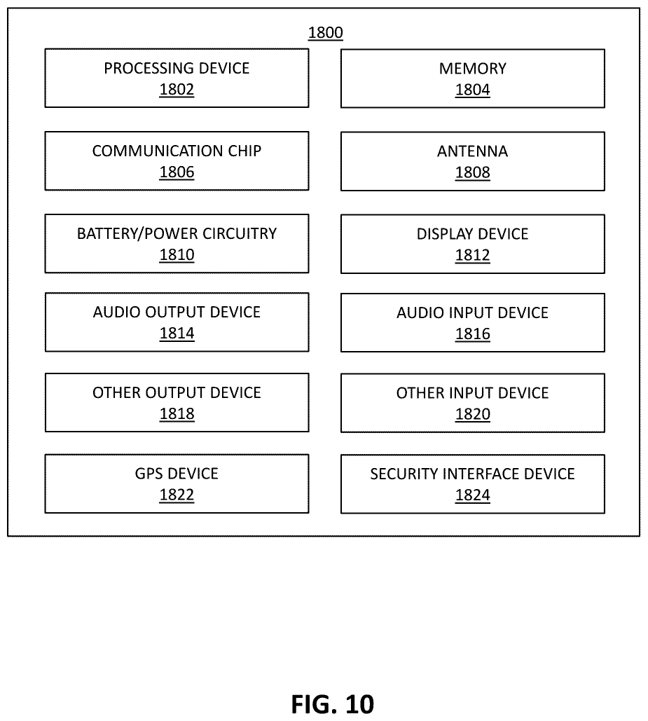

FIG. 7A and 7B are top views of a wafer and dies that include one or more IC structures that may include a microfluidic cooling layer formed over the semiconductor devices in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 1-6, or any further embodiments of the IC structures described herein). After the fabrication of the semiconductor product is complete (e.g., after manufacture of one or more IC devices with a microfluidic cooling layer as described herein, included in a particular electronic component, e.g., in a computing device), the wafer 1500 may undergo a singulation process in which each of the dies 1502 is separated from one another to provide discrete “chips” of the semiconductor product. In particular, devices that include a microfluidic cooling layer as disclosed herein may take the form of the wafer 1500 (e.g., not singulated) or the form of the die 1502 (e.g., singulated). The die 1502 may include one or more transistors (e.g., one or more of the transistors 1640 of FIG. 8, discussed below) and/or supporting circuitry to route electrical signals to the transistors, as well as any other IC components. In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 10) or other logic that is configured to store information in the memory devices or execute instructions stored in the memory array.

FIG. 8 is a cross-sectional side view of an IC device 1600 that may include a microfluidic cooling layer in accordance with any of the embodiments disclosed herein. The IC device 1600 may be formed on a substrate 1602 (e.g., the wafer 1500 of FIG. 7A) and may be included in a die (e.g., the die 1502 of FIG. 7B). The substrate 1602 may be any substrate as described herein. The substrate 1602 may be part of a singulated die (e.g., the dies 1502 of FIG. 7B) or a wafer (e.g., the wafer 1500 of FIG. 7A).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The IC device 1600 may include a microfluidic cooling layer at any suitable location in the IC device 1600.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 8 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 8). Although a particular number of interconnect layers 1606-1610 is depicted in FIG. 8, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 8. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 8. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

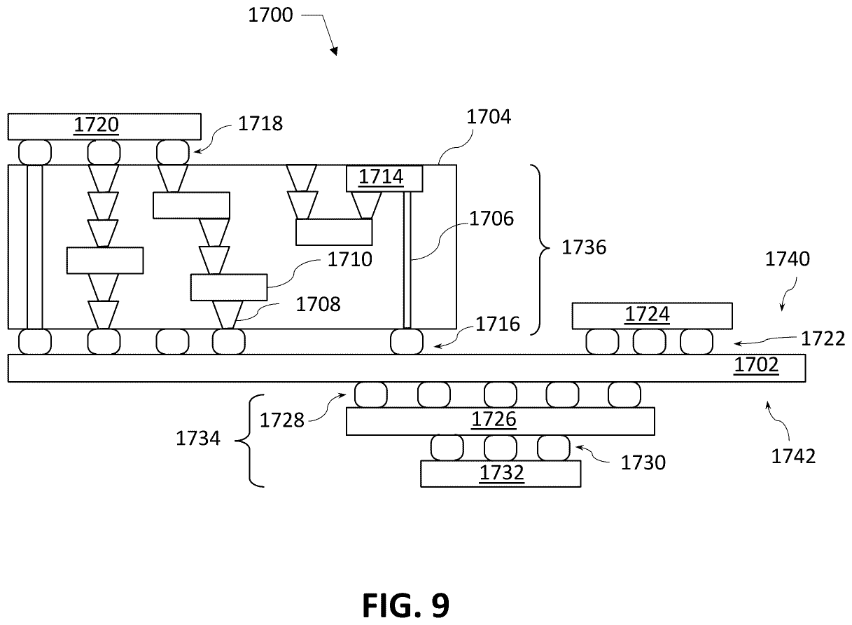

FIG. 9 is a cross-sectional side view of an IC device assembly 1700 that may include a microfluidic cooling layer in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 9 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 9), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 9, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 7B), an IC device (e.g., the IC device 1600 of FIG. 8), or any other suitable component. In some embodiments, the IC package 1720 may include a microfluidic cooling layer, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 9, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 9 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 10 is a block diagram of an example computing device 1800 that may include one or more components including a microfluidic cooling layer in accordance with any of the embodiments disclosed herein. For example, any suitable ones of the components of the computing device 1800 may include a die (e.g., the die 1502 (FIG. 7B)) having a microfluidic cooling layer. Any one or more of the components of the computing device 1800 may include, or be included in, an IC device 1600 (FIG. 8). Any one or more of the components of the computing device 1800 may include, or be included in, an IC device assembly 1700 (FIG. 9).

A number of components are illustrated in FIG. 10 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 10, but the computing device 1800 may include interface circuitry for coupling to the one or more components. For example, the computing device 1800 may not include a display device 1812, but may include display device interface circuitry (e.g., a connector and driver circuitry) to which a display device 1812 may be coupled. In another set of examples, the computing device 1800 may not include an audio input device 1816 or an audio output device 1814, but may include audio input or output device interface circuitry (e.g., connectors and supporting circuitry) to which an audio input device 1816 or audio output device 1814 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random-access memory (STT-MRAM).

In some embodiments, the computing device 1800 may include a communication chip 1806 (e.g., one or more communication chips). For example, the communication chip 1806 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1806 may implement any of a number of wireless standards or protocols, including but not limited to Institute for Electrical and Electronic Engineers (IEEE) standards including Wi-Fi (IEEE 1402.11 family), IEEE 1402.18 standards (e.g., IEEE 1402.18-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.18 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.18 standards. The communication chip 1806 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1806 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1806 may operate in accordance with other wireless protocols in other embodiments. The computing device 1800 may include an antenna 1808 to facilitate wireless communications and/or to receive other wireless communications (such as AM or FM radio transmissions).

In some embodiments, the communication chip 1806 may manage wired communications, such as electrical, optical, or any other suitable communication protocols (e.g., the Ethernet). As noted above, the communication chip 1806 may include multiple communication chips. For instance, a first communication chip 1806 may be dedicated to shorter-range wireless communications such as Wi-Fi or Bluetooth, and a second communication chip 1806 may be dedicated to longer-range wireless communications such as GPS, EDGE, GPRS, CDMA, WiMAX, LTE, EV-DO, or others. In some embodiments, a first communication chip 1806 may be dedicated to wireless communications, and a second communication chip 1806 may be dedicated to wired communications.

The computing device 1800 may include a battery/power circuitry 1810. The battery/power circuitry 1810 may include one or more energy storage devices (e.g., batteries or capacitors) and/or circuitry for coupling components of the computing device 1800 to an energy source separate from the computing device 1800 (e.g., AC line power).

The computing device 1800 may include a display device 1812 (or corresponding interface circuitry, as discussed above). The display device 1812 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1814 (or corresponding interface circuitry, as discussed above). The audio output device 1814 may include any device that generates an audible indicator, such as speakers, headsets, or earbuds, for example.

The computing device 1800 may include an audio input device 1816 (or corresponding interface circuitry, as discussed above). The audio input device 1816 may include any device that generates a signal representative of a sound, such as microphones, microphone arrays, or digital instruments (e.g., instruments having a musical instrument digital interface (MIDI) output).

The computing device 1800 may include another output device 1818 (or corresponding interface circuitry, as discussed above). Examples of the other output device 1818 may include an audio codec, a video codec, a printer, a wired or wireless transmitter for providing information to other devices, or an additional storage device.

The computing device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may include a global positioning system (GPS) device 1822 (or corresponding interface circuitry, as discussed above). The GPS device 1822 may be in communication with a satellite-based system and may receive a location of the computing device 1800, as known in the art.

The computing device 1800 may include a security interface device 1824. The security interface device 1824 may include any device that provides security features for the computing device 1800 or for any individual components therein (e.g., for the processing device 1802 or for the memory 1804). Examples of security features may include authorization, access to digital certificates, access to items in keychains, etc. Examples of the security interface device 1824 may include a software firewall, a hardware firewall, an antivirus, a content filtering device, or an intrusion detection device.

The computing device 1800 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

### Select Examples

The following paragraphs provide various examples of the embodiments disclosed herein.

Example 1 provides an IC device including a first interconnect region including a first plurality of metal layers; a device region including a plurality of transistors, the device region over the first interconnect region; a second interconnect region including a second plurality of metal layers, the second interconnect region over the device region; and a microfluidic channel over the second interconnect region.

Example 2 provides the IC device of example 1, further including a microfluidic cooling layer, the microfluidic cooling layer including a plurality of microfluidic channels including the microfluidic channel.

Example 3 provides the IC device of example 2, where the plurality of microfluidic channels are coupled to a first port and a second port.

Example 4 provides the IC device of example 2 or 3, the microfluidic cooling layer including a carrier wafer having the plurality of microfluidic channels formed therein.

Example 5 provides the IC device of example 4, the carrier wafer including silicon.

Example 6 provides the IC device of any of examples 2-5, further including an interface layer between the second interconnect region and the microfluidic cooling layer.

Example 7 provides the IC device of example 6, further including silicon nitride between the interface layer and the microfluidic channel.

Example 8 provides the IC device of example 7, where the silicon nitride forms a hermetic seal under the microfluidic channel.

Example 9 provides the IC device of any of examples 2-8, where a first subset of the plurality of microfluidic channels are arranged at a first pitch, and a second subset of the plurality of microfluidic channels are arranged at a second pitch.

Example 10 provides an IC device including a device region including a plurality of transistors; a dummy interconnect region including a plurality of metal layers, the dummy interconnect region over the device region and not coupled to the plurality of transistors; and a microfluidic cooling layer over the dummy interconnect region, the microfluidic cooling layer including a plurality of microfluidic channels.

Example 11 provides the IC device of example 10, where the plurality of microfluidic channels are coupled to a first port and a second port.

Example 12 provides the IC device of example 11, where the first port and the second port extend in a direction opposite from the dummy interconnect region.

Example 13 provides the IC device of any of examples 10-12, the microfluidic cooling layer including a carrier wafer having the plurality of microfluidic channels formed therein.

Example 14 provides the IC device of any of examples 10-13, further including a bonding interface between the dummy interconnect region and the microfluidic cooling layer.

Example 15 provides the IC device of example 14, further including a sealant between the bonding interface and the microfluidic channel.

Example 16 provides the IC device of example 15, where the sealant includes silicon nitride.

Example 17 provides the IC device of any of examples 10-12, where a first subset of the plurality of microfluidic channels are arranged at a first pitch, and a second subset of the plurality of microfluidic channels are arranged at a second pitch.

Example 18 provides a method for forming an IC device including forming a device layer including a plurality of transistors; forming a plurality of dummy layers over the device layer; forming a plurality of microfluidic channels in a support structure; and arranging the support structure having the plurality of microfluidic channels formed therein over the dummy layers.

Example 19 provides the method of example 18, where arranging the support structure over the dummy layers includes coupling the support structure to a top face of the dummy layers with a bonding material.

Example 20 provides the method of example 18 or 19, further including forming a plurality of interconnect layers on an opposite side of the device layer form the plurality of dummy layers.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device comprising:
a first interconnect region comprising a first plurality of metal layers;
a device region comprising a plurality of transistors, the device region over the first interconnect region;
a second interconnect region comprising a second plurality of metal layers, the second interconnect region over the device region; and
a microfluidic channel over the second interconnect region.

2. The IC device of claim 1, further comprising a microfluidic cooling layer, the microfluidic cooling layer comprising a plurality of microfluidic channels including the microfluidic channel.

3. The IC device of claim 2, wherein the plurality of microfluidic channels are coupled to a first port and a second port.

4. The IC device of claim 2, the microfluidic cooling layer comprising a carrier wafer having the plurality of microfluidic channels formed therein.

5. The IC device of claim 4, the carrier wafer comprising silicon.

6. The IC device of claim 2, further comprising an interface layer between the second interconnect region and the microfluidic cooling layer.

7. The IC device of claim 6, further comprising silicon nitride between the interface layer and the microfluidic channel.

8. The IC device of claim 7, wherein the silicon nitride forms a hermetic seal under the microfluidic channel.

9. The IC device of claim 2, wherein a first subset of the plurality of microfluidic channels are arranged at a first pitch, and a second subset of the plurality of microfluidic channels are arranged at a second pitch.

10. An integrated circuit (IC) device comprising:
a device region comprising a plurality of transistors;
a dummy interconnect region comprising a plurality of metal layers, the dummy interconnect region over the device region and not coupled to the plurality of transistors; and
a microfluidic cooling layer over the dummy interconnect region, the microfluidic cooling layer comprising a plurality of microfluidic channels.

11. The IC device of claim 10, wherein the plurality of microfluidic channels are coupled to a first port and a second port.

12. The IC device of claim 11, wherein the first port and the second port extend in a direction opposite from the dummy interconnect region.

13. The IC device of claim 10, the microfluidic cooling layer comprising a carrier wafer having the plurality of microfluidic channels formed therein.

14. The IC device of claim 10, further comprising a bonding interface between the dummy interconnect region and the microfluidic cooling layer.

15. The IC device of claim 14, further comprising a sealant between the bonding interface and the microfluidic channel.

16. The IC device of claim 15, wherein the sealant comprises silicon nitride.

17. The IC device of claim 10, wherein a first subset of the plurality of microfluidic channels are arranged at a first pitch, and a second subset of the plurality of microfluidic channels are arranged at a second pitch.

18. A method for forming an integrated circuit (IC) device comprising:
forming a device layer comprising a plurality of transistors;
forming a plurality of dummy layers over the device layer;
forming a plurality of microfluidic channels in a support structure; and
arranging the support structure having the plurality of microfluidic channels formed therein over the dummy layers.

19. The method of claim 18, wherein arranging the support structure over the dummy layers comprises coupling the support structure to a top face of the dummy layers with a bonding material.

20. The method of claim 18, further comprising forming a plurality of interconnect layers on an opposite side of the device layer form the plurality of dummy layers.
